(19) United States
(12) Patent Application Publication
(10) Pub. No.: US 2006/0211181 A1
(43) Pub. Date: Sep. 21, 2006

(54) Method of manufacturing polysilicon thin film transistor plate and liquid crystal display including polysilicon thin film transistor plate manufactured by the method

(76) Inventor: Se-jin Chung, Yongin-si (KR)

Correspondence Address: CANTOR COLBURN LLP, 55 Griffin Road South, Bloomfield, CT, 06002, US

(21) Appl. No.: 11/378,861

(22) Filed: Mar. 17, 2006

(30) Foreign Application Priority Data
Mar. 17, 2005 (KR) 10-2005-0022276

(51) Int. Cl. H01L 21/84; H01L 21/00

(52) U.S. Cl. 438/149

(57) ABSTRACT

Provided are a method of manufacturing a polysilicon thin film transistor plate, which includes leveling the surface of crystallized polysilicon having protruding grains at grain boundaries to improve the electrical characteristics of an active layer, and a liquid crystal display including a polysilicon thin film transistor plate manufactured by the method. The method of manufacturing a polysilicon thin film transistor plate includes loading a substrate on which polysilicon grains are formed, removing protruding grains at grain boundaries among the polysilicon grains by chemical mechanical polishing (“CMP”) and forming a polished substrate, cleaning the polished substrate and forming a cleaned substrate, and unloading the cleaned substrate.

This application claims priority to Korean Patent Application No. 10-2005-0022276, filed on Mar. 17, 2005 and all the benefits accruing therefrom under 35 U.S.C. §119, and the contents of which in its entirety are herein incorporated by reference.

### BACKGROUND OF THE INVENTION

1. Field of the Invention

The present invention relates to a method of manufacturing a polysilicon thin film transistor plate and a liquid crystal display including a polysilicon thin film transistor plate manufactured by the method. More particularly, the present invention relates to a method of manufacturing a polysilicon thin film transistor plate, which includes leveling the surface of crystallized polysilicon having protruding grains at grain boundaries to improve electrical characteristics of an active layer, and a liquid crystal display including a polysilicon thin film transistor plate manufactured by the method.

2. Description of the Related Art

Generally, an active layer constituting a thin film transistor (“TFT”) is formed using hydrogenated amorphous silicon (“a-Si”) with no periodic lattice structure or solid-phase crystalline polysilicon according to the crystal phase form of the active layer.

Amorphous silicon is capable of forming a thin film by low-temperature deposition, and thus is widely used for a switching device of a liquid crystal panel employing mainly a glass substrate having a low melting point. In particular, when a hydrogenated amorphous silicon active layer used for a switching device is exposed to light, photocurrent generated by photoelectric conversion serves as off-state leakage current adversely affecting the operation of the switching device.

Furthermore, the hydrogenated amorphous silicon active layer, even when not exposed to light, induces defects such as dangling bonds which are aperiodic lattice characteristics specific to amorphous silicon, and poor electron flow, thereby lowering device operation characteristics.

Therefore, an amorphous silicon thin film lowers the electrical characteristics and reliability of liquid crystal panel driving devices and renders the fabrication of large-scale display devices difficult. Generally, pixel driving devices with good electrical characteristics, for example, high field-effect mobility (30 □/VS), high frequency operation characteristics, and low leakage current are necessary for commercialization of liquid crystal displays (“LCDs”) for large-scale, high-definition panels, pixel driving circuits, integrated laptop computers, and wall mounted televisions.

On the other hand, with respect to a polysilicon active layer, less surface defects are produced and the operation speed of a TFT is about 100 to 200 times faster as compared to an amorphous silicon active layer.

A TFT including a polysilicon active layer exhibits rapid operation characteristics and can be sufficiently operated by working together with an external high-speed driving integrated circuit, and thus it can be used as a switching device suitable for real-time image displays such as large-scale LCDs.

Recently, a sequential lateral solidification (“SLS”) process has been suggested for phase transformation from amorphous silicon to polysilicon. According to the SLS process, a laser beam is irradiated onto an amorphous silicon thin film deposited on a substrate by laser annealing, etc., to form a polysilicon film.

That is, the SLS process is a method of forming a polysilicon film by melting amorphous silicon deposited on a substrate by instantaneous supply of laser energy and cooling the molten amorphous silicon.

According to the SLS process for crystallization of an amorphous silicon layer, however, while the amorphous silicon layer is melted and crystallized, grains are protruded from a fragile surface of the silicon layer, which leads to surface roughness.

FIG. 1 shows a surface of a crystallized polysilicon layer obtained by a conventional crystallization method. As shown in FIG. 1, the crystallized polysilicon layer has a rough surface due to protruding grains, because the density of molten silicon before crystallization of amorphous silicon is higher than that of solid-phase silicon.

Such protruding grains lead to local current concentration during device operation, thereby lowering device characteristics. In this respect, surface treatment of crystallized polysilicon with deionized water and hydrofluoric acid has been suggested to remove protruding grains. However, the improvement effect is insignificant.

### BRIEF SUMMARY OF THE INVENTION

The present invention provides a method of manufacturing a polysilicon thin film transistor (“TFT”) plate, which includes leveling the surface of crystallized polysilicon having protruding grains at grain boundaries to improve the electrical characteristics of an active layer.

The present invention also provides a liquid crystal display (“LCD”) including a polysilicon TFT plate manufactured by the method.

The above stated method of manufacturing a polysilicon TFT plate and LCD including the polysilicon TFT plate as well as other features and advantages of the present invention will become clear to those skilled in the art upon review of the following description.

According to exemplary embodiments of the present invention, there is provided a method of manufacturing a polysilicon TFT plate, the method including loading a substrate on which polysilicon grains are formed, removing protruding grains at grain boundaries among the polysilicon grains by chemical mechanical polishing (“CMP”) and forming a polished substrate, cleaning the polished substrate and forming a cleaned substrate, and unloading the cleaned substrate.

According to other exemplary embodiments of the present invention, there is provided an LCD including a polysilicon TFT plate manufactured by the above-described method.

According to other exemplary embodiments of the present invention, there is provided an LCD including a substrate and an active layer formed on the substrate patterned from a polysilicon layer on the substrate, wherein the polysilicon layer is leveled by chemical mechanical polishing to remove protruding polysilicon grains.

### BRIEF DESCRIPTION OF THE DRAWINGS

The above and other features and advantages of the present invention will become more apparent by describing in detail exemplary embodiments thereof with reference to the attached drawings in which:

FIG. 1 is a view showing a surface of a crystallized polysilicon layer obtained by a conventional crystallization method;

FIG. 2 is a diagram illustrating an exemplary embodiment of a liquid crystal display (“LCD”) according to the present invention;

FIG. 3 is an equivalent circuit view illustrating an exemplary pixel of the exemplary embodiment of the LCD of FIG. 2;

FIGS. 4A and 4B are sectional views illustrating exemplary phase transformation from amorphous silicon to polysilicon in an exemplary embodiment of a method of manufacturing an exemplary polysilicon thin film transistor (“TFT”) plate according to the present invention;

FIG. 5 is a view illustrating the crystallization of amorphous silicon to polysilicon by excimer laser annealing in manufacturing an exemplary polysilicon TFT plate according to the present invention;

FIG. 6 is a diagram illustrating an exemplary apparatus for removing protruding grains on a polysilicon substrate used in an exemplary embodiment of a method of manufacturing an exemplary polysilicon TFT plate according to the present invention;

FIG. 7 is a schematic perspective view illustrating an exemplary chemical mechanical polishing machine used in the exemplary embodiment of the method of manufacturing an exemplary polysilicon TFT plate according to the present invention shown in FIG. 6; and

FIG. 8 is a flow diagram illustrating an exemplary process of removing protruding polysilicon grains on a substrate in an exemplary embodiment of a method of manufacturing an exemplary polysilicon TFT plate according to the present invention.

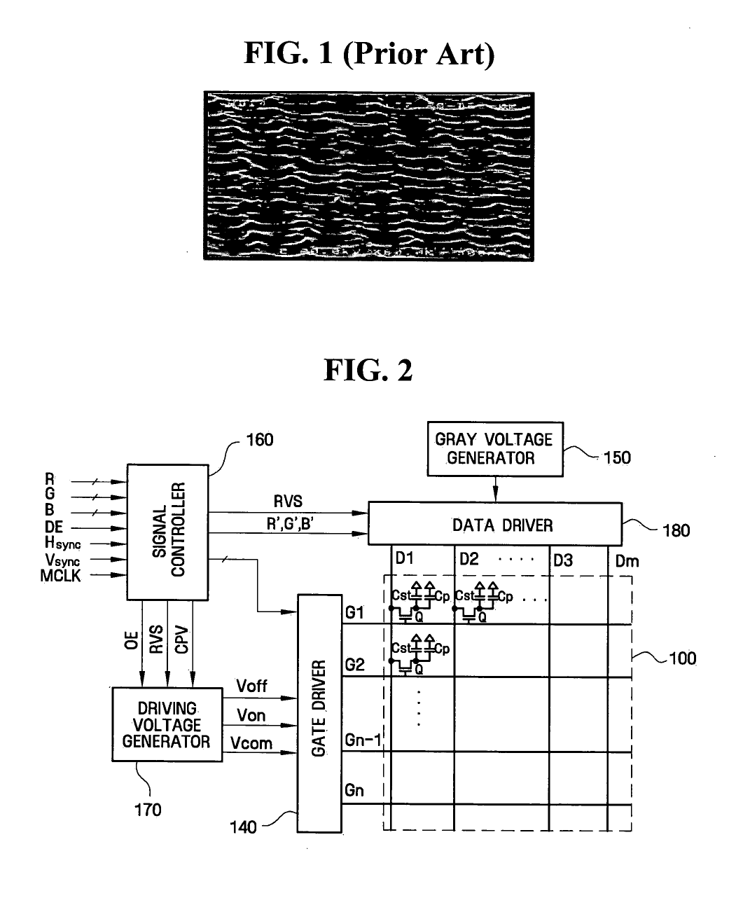

### DETAILED DESCRIPTION OF THE INVENTION

The invention will now be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, the present invention will be described in detail with reference to the accompanying drawings.

Exemplary embodiments of a method of manufacturing a thin film transistor-liquid crystal display (“TFT-LCD”) according to the present invention will now be described more fully with reference to FIGS. 2 through 8.

FIG. 2 is a diagram illustrating an exemplary embodiment of an LCD according to the present invention.

Referring to FIG. 2, a TFT-LCD includes a liquid crystal panel 100, a gate driver 140 and a data driver 180 connected to the liquid crystal panel 100, a driving voltage generator 170 connected to the gate driver 140, a gray voltage generator 150 connected to the data driver 180, and a signal controller 160 controlling the gate driver 140, the data driver 180, and the driving voltage generator 170.

The liquid crystal panel 100 includes a plurality of pixels comprised in a region defined by a plurality of gate lines G1, . . . , Gn and a plurality of data lines D1, . . . , Dm as shown in its equivalent circuit. The pixels are arranged in a matrix configuration on the liquid crystal panel 100. Each pixel includes a TFT Q connected to corresponding gate and data lines, and a liquid crystal capacitor Cp and a storage capacitor Cst connected to the TFT Q.

The plurality of the gate lines G1, . . . , Gn receive gate signals from the gate driver 140 and are responsible for gate signal transmission to the pixels connected thereto and extend in a row direction and the plurality of the data lines D1, . . . , Dm receive data signals from the data driver 180 and are responsible for data signal transmission to the pixels connected thereto and extend in a column direction.

The TFT Q is a three-terminal device in which a control terminal, such as a gate electrode, is connected to a corresponding gate line among the plurality of the gate lines G1, . . . , Gn, an input terminal, such as a source electrode, is connected to a corresponding data line among the plurality of the data lines D1, . . . , Dm, and an output terminal, such as a drain electrode, is connected to a terminal of the liquid crystal capacitor Cp and a terminal of the storage capacitor Cst.

In an alternative embodiment, the other terminal of the storage capacitor Cst may be connected to the adjacent upper gate line (called “previous gate line”, hereinafter). The former type of the storage capacitor Cst is called a separate wire type, and the latter type of the storage capacitor Cst is called a previous gate type.

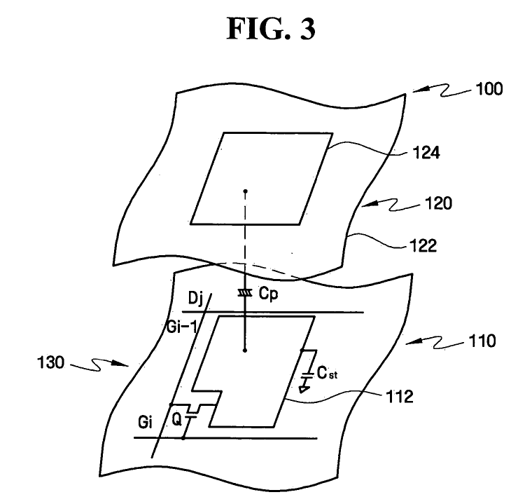

The structure of the liquid crystal panel 100 is schematically illustrated in FIG. 3. For brevity of explanation, one pixel is illustrated in FIG. 3.

Referring to FIG. 3, the liquid crystal panel 100 includes a lower plate 110, an upper plate 120 facing the lower plate 110, and a liquid crystal layer 130 interposed between the two plates 110 and 120. For the illustrated pixel, the lower plate 110 includes gate lines Gi-1 and Gi, a data line Dj, a TFT Q, a liquid crystal capacitor Cp, and a storage capacitor Cst. The liquid crystal capacitor Cp has two electrodes, one being a pixel electrode 112 of the lower plate 110 and the other being a common electrode 122 of the upper plate 120, and the liquid crystal layer 130 interposed between the two electrodes 112 and 122 serves as a dielectric.

The pixel electrode 112 is connected to the TFT Q, such as to the output terminal or drain electrode of the TFT Q. The common electrode 122 is formed on the entire surface, or substantially the entire surface, of the upper plate 120 and a common voltage (see Vcom of FIG. 2) is applied thereto.

Here, the arrangement of liquid crystal molecules is changed according to an electric field generated by the pixel electrode 112 and the common electrode 122, and light transmitted through the liquid crystal layer 130, such as from a backlight assembly, is polarized accordingly. Such a change of the polarization leads to a change in light transmittance by polarizers (not shown) attached to the lower and upper plates 110 and 120, such as on outer surfaces of the lower and upper plates 110 and 120.

Meanwhile, a separate wire, such as a storage electrode line, to which the common voltage Vcom is applied may be formed on the lower plate 110 in such a way to overlap with the pixel electrode 112 to thereby form the storage capacitor Cst. In a previous gate type, the pixel electrode 112 overlaps with the previous gate line Gi-1 with a dielectric layer interposed therebetween to form the storage capacitor Cst.

In an alternative embodiment, unlike in FIG. 3, the common electrode 122 may also be formed on the lower plate 110 instead of the upper plate 120. In this case, the pixel electrode 112 and the common electrode 122 are formed linearly, such as in alternating stripes.

Meanwhile, each pixel must be designed to create colors to enable color display. In this regard, a red, green, or blue color filter 124 may be formed on the upper plate 120 corresponding to the pixel electrode 112, although other color filters would also be within the scope of these embodiments.

As shown in FIG. 3, the color filter 124 is mainly formed on a predetermined region of the upper plate 120. However, the color filter 124 may alternatively be formed on an upper or lower region of the pixel electrode 112 of the lower plate 110.

With reference again to FIG. 2, the driving voltage generator 170 generates a gate-on voltage Von for turning on the TFT Q, a gate-off voltage Voff for turning off the TFT Q, etc.

The gray voltage generator 150 generates a plurality of gray voltages related to the brightness of the LCD.

The gate driver 140, also called a scan driver, is connected to the gate lines G1, . . . , Gn of the liquid crystal panel 100 and supplies a gate signal composed of the combination of the gate-on voltage Von and the gate-off voltage Voff from the driving voltage generator 170, to the gate lines G1, . . . , Gn.

The data driver 180, also called a source driver, is connected to the data lines D1, . . . , Dm of the liquid crystal panel 100, and it selects a gray voltage from the gray voltage generator 150 and supplies the gray voltage as a data signal to the data lines D1, . . . , Dm.

The signal controller 160 generates control signals controlling the operation of the gate driver 140, the data driver 180, and the driving voltage generator 170, and supplies the respective corresponding control signals to the gate driver 140, the data driver 180, and the driving voltage generator 170.

The TFT Q includes an active layer made of polysilicon to accomplish rapid operation characteristics. A method of manufacturing such a polysilicon TFT plate will now be described.

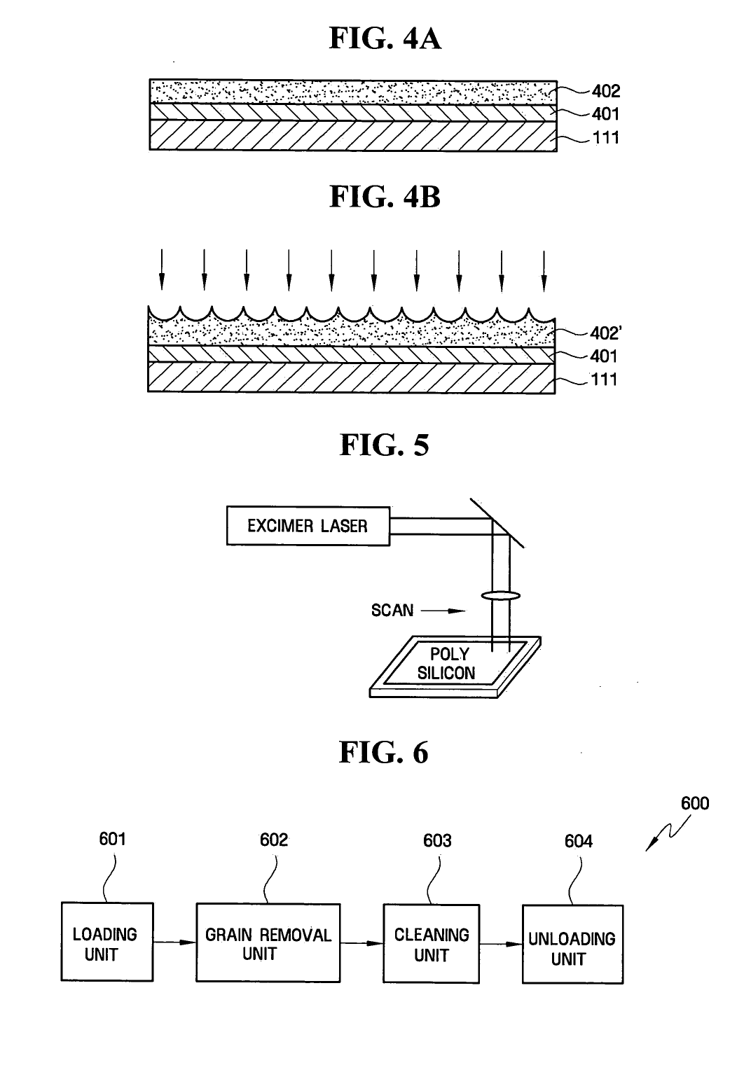

FIGS. 4A and 4B are sectional views illustrating phase transformation from amorphous silicon to polysilicon in an exemplary embodiment of a method of manufacturing an exemplary polysilicon TFT plate according to the present invention.

Referring to FIG. 4A, a buffer layer 401 is formed to a predetermined thickness on the entire surface, or substantially the entire surface, of a substrate 111 to prevent the diffusion of impurities generated in a subsequent process. The substrate 111 may be, for example, an insulating material such as transparent glass or plastic, and may form a supporting layer in the lower plate 110. An amorphous silicon layer 402 is formed to a thickness of about 300 to 1,0001 on the entire surface, or substantially the entire surface, of the buffer layer 401 covering the substrate 111 using plasma-enhanced chemical vapor deposition (“PECVD”), low-pressure CVD (“LPCVD”), etc. Then, referring to FIG. 4B, the amorphous silicon layer 402 is crystallized into a polysilicon layer 402′ with many grains using a laser annealing process as a polysilicon formation method. According to the laser annealing process, a polysilicon film is formed by melting amorphous silicon deposited on a substrate by instantaneous supply (several tens to hundreds nanoseconds) of laser energy and cooling the molten amorphous silicon.

FIG. 5 is a view illustrating the crystallization of amorphous silicon to polysilicon by excimer laser annealing in manufacturing an exemplary polysilicon TFT plate according to the present invention. Referring to FIG. 5, energy beam is applied onto the substrate 111 on which the amorphous silicon layer 402 is deposited while moving the substrate 111 to melt the amorphous silicon layer 402.

In an exemplary embodiment, excimer laser, which is a pulsed UV beam, is used as the energy beam. Even though the melting temperature of amorphous silicon is high, since the excimer laser annealing is performed for a short time (e.g., several tens nanoseconds), no damage to the substrate supporting the amorphous silicon layer is caused.

The excimer laser is scanned at a predetermined repetition rate onto the amorphous silicon layer 402 formed on the substrate 111.

When the excimer laser scanning is performed over the entire surface of the substrate 111, an upper portion of the amorphous silicon layer 402 starts to melt. At this time, the excimer laser energy is appropriately adjusted so that the amorphous silicon layer 402 formed on the substrate 111 is mostly melted, and a portion of the amorphous silicon layer 402 at its interface with the buffer layer 401 is not melted to act as seeds in a subsequent crystallization process.

When the amorphous silicon layer 402 is crystallized using excimer laser annealing, the molten amorphous silicon is solidified on the basis of seeds present at an interface between the buffer layer 401 and the amorphous silicon layer 402 as crystalline nuclei to thereby form many crystalline grains with grain boundaries.

At this time, the grains are protruded from a fragile surface of the polysilicon layer 402′, which leads to surface roughness of the polysilicon layer 402′. In view of this problem, a process for removing protruding grains at a surface of the polysilicon layer 402′ is performed.

Accordingly, the process for removing the protruding grains at a surface of the polysilicon layer 402′ is performed using an exemplary surface leveling apparatus 600 as described with respect to FIG. 6.

FIG. 6 is a diagram illustrating an exemplary apparatus for removing protruding grains on a polysilicon substrate used for an exemplary embodiment of a method of manufacturing an exemplary polysilicon TFT plate according to the present invention. Referring to FIG. 6, the surface leveling apparatus 600 includes a loading unit 601, a grain removal unit 602, a cleaning unit 603, and an unloading unit 604.

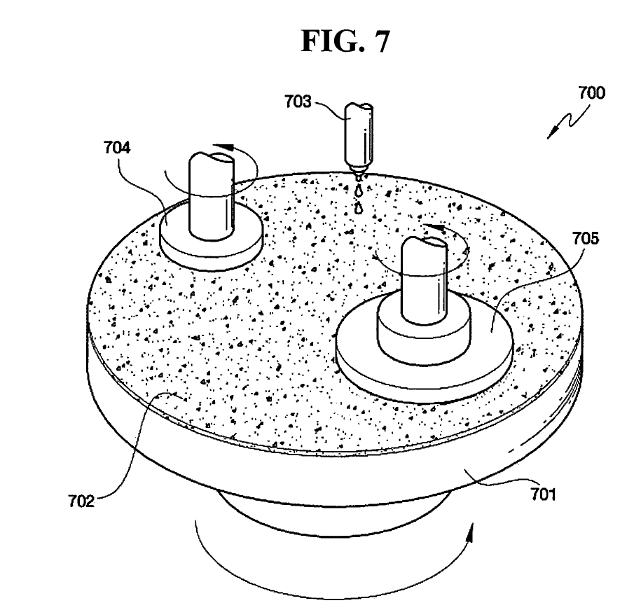

The loading unit 601 is used to load a crystallized polysilicon substrate thereon, such as the substrate 111 having the polysilicon layer 402′ shown in FIG. 4B. The loading unit 601 includes an inversion unit (not shown) for inverting the polysilicon substrate so that a polysilicon surface of the polysilicon substrate faces downward, with the substrate positioned above the polysilicon layer to undergo chemical mechanical polishing (“CMP”) by the grain removal unit 602, and a head (see 705 of FIG. 7) for fixedly moving the polysilicon substrate. The head 705 can fix the polysilicon substrate thereto by vacuum means.

The grain removal unit 602 is used to remove the protruding grains at the polysilicon substrate. For example, the grain removal unit 602 includes, as shown in FIG. 7, a CMP machine 700, as will be further described below, including a polishing table 701, a polishing pad 702, and a slurry supply unit 703.

The cleaning unit 603 is used to remove a grain residue or slurry present on a surface of the substrate. The cleaning unit 603 is formed in-line with the grain removal unit 602 to continuously perform the grain removal and the cleaning.

The unloading unit 604 inverts the substrate by an inversion unit (not shown) so that the polysilicon surface of the substrate faces upward, with the substrate positioned below the polysilicon layer, and then unloads the substrate.

Hereinafter, the CMP machine 700 included in the grain removal unit 602 will be further described with reference to FIG. 7.

FIG. 7 is a schematic perspective view illustrating an exemplary CMP machine used for an exemplary embodiment of a method of manufacturing an exemplary polysilicon TFT plate according to the present invention. Referring to FIG. 7, a polishing pad 702 is disposed on a polishing table 701 of the CMP machine 700, and the polishing table 701 supports and rotates the polishing pad 702.

The polishing pad 702 is attached to an upper surface of the polishing table 701 and directly contacts with a substrate (not shown) to polish the substrate. In particular, the polishing pad 702 may contact a polysilicon surface of the substrate. A plurality of micropores are formed on a surface of the polishing pad 702 to receive slurry from a slurry supply unit 703.

The slurry supply unit 703 serves to supply the slurry necessary for CMP to the polishing pad 702 attached to the upper surface of the polishing table 701. The slurry supply unit 703 may include a sprayer (not shown) for uniformly spraying the slurry onto the polishing pad 702.

In addition, the CMP machine 700 may further include a pad conditioner 704. As polishing proceeds, a surface of the polishing pad 702 becomes glazed, and thus, a contact area between the substrate and the polishing pad 702 increases, thereby lowering polishing uniformity and evenness. Thus, the pad conditioner 704 serves to improve the surface state of the polishing pad 702, such as by cutting a worn-out surface zone of the polishing pad 702 to expose a new surface. Therefore, the micropores formed in the polishing pad 702 are prevented from clogging, and the lifetime and performance of the polishing pad 702 can be maintained.

Hereinafter, an exemplary process of removing protruding grains on a polysilicon substrate using the exemplary surface leveling apparatus 600 shown in FIG. 6 will be described with reference to FIGS. 6 through 8.

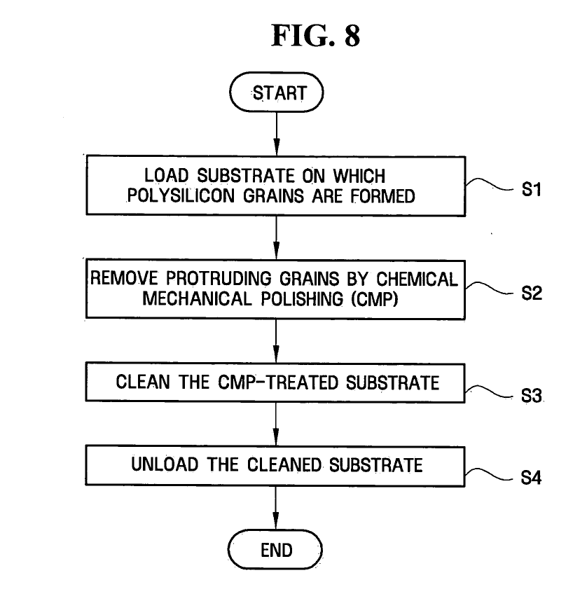

FIG. 8 is a flow diagram illustrating an exemplary process of removing protruding grains on a substrate in an exemplary embodiment of a method of manufacturing an exemplary polysilicon TFT plate according to the present invention.

Referring to FIGS. 6 through 8, a substrate on which polysilicon grains are formed is loaded as described in SI, such as by the loading unit 601.

That is, the substrate is inverted by 180 degrees using an inversion unit so that a polysilicon grain surface of the substrate faces downward, and then fixed to the head 705 of the CMP machine 700. Prior to loading the substrate, the substrate may also be pre-cleaned with deionized water.

Next, protruding grains on the substrate are removed by CMP, as shown by S2, such as by the grain removal unit 602.

The substrate fixed to the head 705 is transferred to the grain removal unit 602 and is then subjected to CMP to remove the protruding grains on the polysilicon grain surface of the substrate.

The substrate fixed to the head 705 is disposed on the polishing pad 702 positioned on the polishing table 701 of the CMP machine 700. That is, a protruding grain surface of the substrate faces with the polishing pad 702. As the polishing pad 702 is rotated, the head 705 pressedly rotates the substrate to remove the protruding grains.

At this time, the slurry supply unit 703 supplies slurry between the substrate and the polishing pad 702 to facilitate polishing. As used herein, the term “slurry” refers to a solution obtained by uniformly dispersing and mixing microparticles for mechanical polishing and an acid or base solution for chemical reaction with a substrate to be polished in deionized water.

The slurry includes an abrasive in the shape of microparticles for mechanical polishing. The abrasive must satisfy the following requirements: high polishing speed and low surface scratch rate. In this regard, the abrasive may be metal oxide such as silica (SiO₂), ceria (CeO₂), alumina (Al₂O₃), zirconia (ZrO₂), tin oxide (SnO₂), and manganese oxide (MnO₂). Preferably, silica, ceria, or alumina can be used as the abrasive. At this time, the abrasive may have a particle size of 50 to 200 nm.

Next, the CMP-treated substrate is cleaned as shown in S3, such as by the cleaning unit 603.

The CMP-treated substrate fixed to the head 705 is transferred to the cleaning unit 603 and cleaned. In the cleaning unit 603, grain residue and slurry present on the substrate are removed by cleaning. At this time, the cleaning may be performed with a brush, ultrasonic treatment, deionized water, or isopropyl alcohol, but is not limited to the illustrated examples. One or more of the referenced cleaning methods may also be used.

Next, the cleaned substrate is unloaded as described by S4, such as by the unloading unit 604.

The substrate fixed to the head 705 is transferred to the unloading unit 604. In the unloading unit 604, the substrate is inverted by 180 degrees using an inversion unit (not shown) so that the polysilicon surface of the substrate faces upward and is then unloaded.

Although not shown, subsequent processes for manufacturing a polysilicon TFT plate are as follows.

The polysilicon layer, manufactured using the above described method, is patterned to form an active layer. A first insulating layer is formed on the entire surface of the substrate including the active layer.

Then, metal is deposited on the first insulating layer and patterned to form a gate electrode, and may further be patterned to form gate lines. The active layer is implanted with impurity using the gate electrode as a mask to form a source/drain region.

A channel region is defined between the source region and the drain region.

Then, a second insulating layer is formed on the entire surface of the substrate including the gate electrode, and metal is deposited on the second insulating layer and patterned to form a source/drain electrode, and may further be patterned to form data lines. At this time, the source/drain region is connected to the source/drain electrode via contact holes in the first and second insulating layers, thus completing at least a portion of a polysilicon TFT plate including a polysilicon active layer.

As apparent from the above description, in an LCD including a TFT manufactured according to the present invention, device characteristics of an active layer can be improved by removing protruding grains on a substrate.

Although the present invention has been described in connection with the exemplary embodiments of the present invention, it will be apparent to those skilled in the art that various modifications and changes may be made thereto without departing from the scope and spirit of the invention. Therefore, it should be understood that the above embodiments are not limitative, but illustrative in all aspects.

What is claimed is:

1. A method of manufacturing a polysilicon thin film transistor plate, the method comprising:
loading a substrate on which polysilicon grains are formed;
removing protruding grains at grain boundaries among the polysilicon grains by chemical mechanical polishing and forming a polished substrate;
cleaning the polished substrate and forming a cleaned substrate; and
unloading the cleaned substrate.

2. The method of claim 1, wherein removing the protruding grains includes supplying slurry between the substrate and a polishing pad while the polishing pad is rotated in a state wherein the substrate is closely contacted to a surface of the polishing pad.

3. The method of claim 2, further comprising improving a surface state of the polishing pad with a pad conditioner.

4. The method of claim 2, further comprising rotating the substrate independently of a rotation of the polishing pad while the substrate is in contact with the polishing pad.

5. The method of claim 2, wherein the slurry comprises an abrasive selected from alumina, silica, and ceria.

6. The method of claim 5, wherein the abrasive has a particle size of 50 to 200 nm.

7. The method of claim 1, further comprising pre-cleaning the substrate prior to loading the substrate.

8. The method of claim 1, wherein removing protruding grains and cleaning the polished substrate are continuously performed.

9. The method of claim 1, wherein cleaning the polished substrate is performed with a brush, ultrasonic treatment, isopropyl alcohol, and/or deionized water.

10. The method of claim 1, wherein loading the substrate includes inverting the substrate to face the polysilicon grains downwardly and moving the substrate to a chemical mechanical polishing machine.

11. The method of claim 10, wherein unloading the cleaned substrate includes inverting the substrate to face the polysilicon grains upwardly.

12. The method of claim 1, wherein the polysilicon grains are formed in a polysilicon layer on the substrate, and, subsequent to unloading the cleaned substrate, the method further comprising patterning the polysilicon layer to form an active layer of the polysilicon thin film transistor plate.

13. The method of claim 1, further comprising, prior to loading the substrate, providing the substrate with a buffer layer and an amorphous silicon layer on the buffer layer, and laser annealing the amorphous silicon layer to form a polysilicon layer having the polysilicon grains.

14. A liquid crystal display comprising a polysilicon thin film transistor plate manufactured by a method comprising:
loading a substrate on which polysilicon grains are formed;
removing protruding grains at grain boundaries among the polysilicon grains by chemical mechanical polishing and forming a polished substrate;
cleaning the polished substrate and forming a cleaned substrate; and
unloading the cleaned substrate.

15. The liquid crystal display of claim 14, wherein removing the protruding grains includes supplying slurry between the substrate and a polishing pad while the polishing pad is rotated in a state wherein the substrate is closely contacted to a surface of the polishing pad.

16. The liquid crystal display of claim 14, wherein the polysilicon grains are formed in a polysilicon layer on the substrate, and further comprising an active layer of the polysilicon thin film transistor plate formed by patterning the polysilicon layer.

17. The liquid crystal display of claim 16, wherein localized current concentration during operation of the liquid crystal display is substantially prevented in the active layer.

18. The liquid crystal display of claim 14, wherein the polysilicon grains are formed in a polysilicon layer on the substrate, and wherein the polysilicon layer is substantially leveled during removal of the protruding grains.

19. A liquid crystal display comprising:
a substrate; and,
an active layer formed on the substrate patterned from a polysilicon layer on the substrate, wherein the polysilicon layer is leveled by chemical mechanical polishing to remove protruding polysilicon grains.

20. The liquid crystal display of claim 19, further comprising a thin film transistor including a source region and a drain region of the active layer.
